(19) United States
(12) Patent Application Publication
(10) Pub. No.: US 2024/0076140 A1
(43) Pub. Date: Mar. 7, 2024

(54) Article Transport Facility

(71) Applicant: Daifuku Co., Ltd., Osaka-shi (JP)

(72) Inventors: Toyoki Takahashi, Komaki-shi (JP); Hidemoto Fukushima, Komaki-shi (JP); Keisuke Takeno, Komaki-shi (JP); Satoshi Nitta, Komaki-shi (JP)

(21) Appl. No.: 18/239,322

(22) Filed: Aug. 29, 2023

(30) Foreign Application Priority Data
Sep. 1, 2022 (JP) 2022-139480

(51) Int. Cl. B65G 47/46

(52) U.S. Cl. CPC B65G 47/46

(57) ABSTRACT

The article transport facility includes a transport vehicle that travels along a predetermined travel route and transport articles; an unmanned aerial vehicle that flies along a route and transports articles; a transfer section at which articles are transferred to and from the transport vehicle and the unmanned aerial vehicle; and a storage unit arranged at a location along the travel route and stores articles. The storage unit includes a carry-in section to which the transport vehicle carries in articles; a carry-out section from which the transport vehicle carries out articles; one or more storage locations at which articles are stored; and a transport device that transports articles from the carry-in section to the carry-out section via the one or more storage locations. The transport vehicle transports articles from the carry-out section to the transfer section, and the unmanned aerial vehicle transports articles from the one or more storage locations to the transfer section.

### CROSS-REFERENCE TO RELATED APPLICATIONS

This application claims priority to Japanese Patent Application No. 2022-139480 filed Sep. 1, 2022, the disclosure of which is hereby incorporated by reference in its entirety.

### BACKGROUND OF THE INVENTION

### 1. Field of the Invention

The present invention relates to an article transport facility which includes a transport vehicle that travels along a predetermined travel route and transports an article, a transfer section at which articles are transferred to and from the transport vehicle and an unmanned aerial vehicle, and a storage unit that is arranged along the travel route and stores articles.

### 2. Description of Related Art

One example of such an article transport facility is disclosed in JP 2019-94201A (hereinafter referred to as “Patent Document 1”). The reference signs and names in parentheses in the description below are the reference signs and names used in Patent Document 1.

The article transport facility described in Patent Document 1 includes a transport vehicle (1) that travels along a predetermined travel route (transport route 99) and transports an article that is a processing target, such as a semiconductor substrate. Processing devices (91) are provided along the travel route (99) of the transport vehicle (1). A transfer section such as a placement table (St) is provided in correspondence with each of the processing devices (91) and is for the transfer of an article that is a processing target of the corresponding processing device (91), and, at each transfer section, the transport vehicle (1) carries in an article to a processing device (91) or carries out an article from the processing device (91).

The article transport facility described in Patent Document 1 is also provided with a storage (92) and a temporary storage (93) for storing articles. Storage devices such as the storage (92) and the temporary storage (93) are arranged at positions along the travel route (99) of the transport vehicle (1), and the transport vehicle (1) transfers articles to and from transfer sections provided in correspondence with the storage (92) and the temporary storage (93). Also, the article transport facility may also be provided with various types of transport devices such as conveyors and lifters, and the transport vehicle (1) also transfers articles to and from transfer sections of such transport devices.

In the conventional article transport facility described in Patent Document 1, the transport vehicle (1) transfers articles to and from the transfer sections of the processing devices (91), transfers articles to and from the transfer sections of the storage units (92, 93), transfers articles to and from the transfer sections of various transport devices, and transports articles between the processing devices (91), the storage units (92, 93), and the like. In other words, the transport vehicle (1) is required to play many roles. For this reason, a long wait time can possibly elapse from when a processing device (91) is able to immediately start performing article processing until when an article is carried in to the processing device (91) by the transport vehicle (1), and a long wait time can possibly elapse from when the processing device (91) completes article processing until when the article is carried out from the processing device (91) by the transport vehicle (1). Similarly, for devices other than the processing devices as well, if a long wait time elapses from when an article can be carried in to the transfer section until when the article is actually carried in, or from when an article can be carried out from a transfer section until when the article is actually carried out, the efficiency of article transport decreases.

In light of the above-described situation, there is a demand for realization of an article transport facility that can efficiently transport articles.

### SUMMARY OF THE INVENTION

In view of the foregoing, an article transport facility according to an aspect includes:
a transport vehicle configured to travel along a predetermined travel route and transport an article;
an unmanned aerial vehicle configured to fly along a route and transport the article;
a transfer section at which the article is transferrable to and from the transport vehicle and the at least one unmanned aerial vehicle; and
a storage unit arranged at a location along the travel route and configured to store the article,
wherein the storage unit includes:
   a carry-in section to which the transport vehicle carries in the article;
   a carry-out section from which the transport vehicle carries out the article;
   at least one storage location at which the article is storable; and
   a transport device configured to transport the article from the carry-in section to the carry-out section via the at least one storage location,
the transport vehicle transports the article from the carry-out section to the transfer section, and
the unmanned aerial vehicle transports the article from the at least one storage location to the transfer section.

According to this configuration, an article stored at a storage location between the carry-in section and the carry-out section of the storage unit can be transported by the unmanned aerial vehicle. Therefore, even if an article stored in the storage unit cannot be immediately transported to the transfer section of the processing device by the transport vehicle, the article can be quickly transported from the storage unit to the transfer section of the processing device by the unmanned aerial vehicle. Also, in the case where an article becomes needed in the processing device or processing of an article in the processing device is complete, the article can be quickly transported by the unmanned aerial vehicle, without waiting for the arrival of the transport vehicle. Therefore, it is easy to improve the efficiency of article transport between the storage unit and the transfer section, thus making it is easy to improve the efficiency of article processing performed by the processing device. It is thus possible to realize an article transport facility that can efficiently transport articles.

Further features and advantages of the technology according to the present disclosure will become clearer from the following description of exemplary and non-limiting embodiments given with reference to the drawings.

### BRIEF DESCRIPTION OF THE DRAWINGS

FIG. 1 is a plan view showing an example of a layout of an article transport facility.

FIG. 2 is a control block diagram of the article transport facility.

FIG. 3 is a schematic plan view of a storage unit.

FIG. 4 is a schematic plan view of the storage unit.

FIG. 5 is a side view of a transport vehicle.

FIG. 6 is a schematic perspective view of the storage unit.

FIG. 7 is a schematic side view of the storage unit.

FIG. 8 is a schematic plan view of the storage unit.

FIG. 9 is a schematic plan view of the storage unit.

FIG. 10 is a schematic perspective view of the storage unit.

### DESCRIPTION OF THE INVENTION

### 1. Embodiment

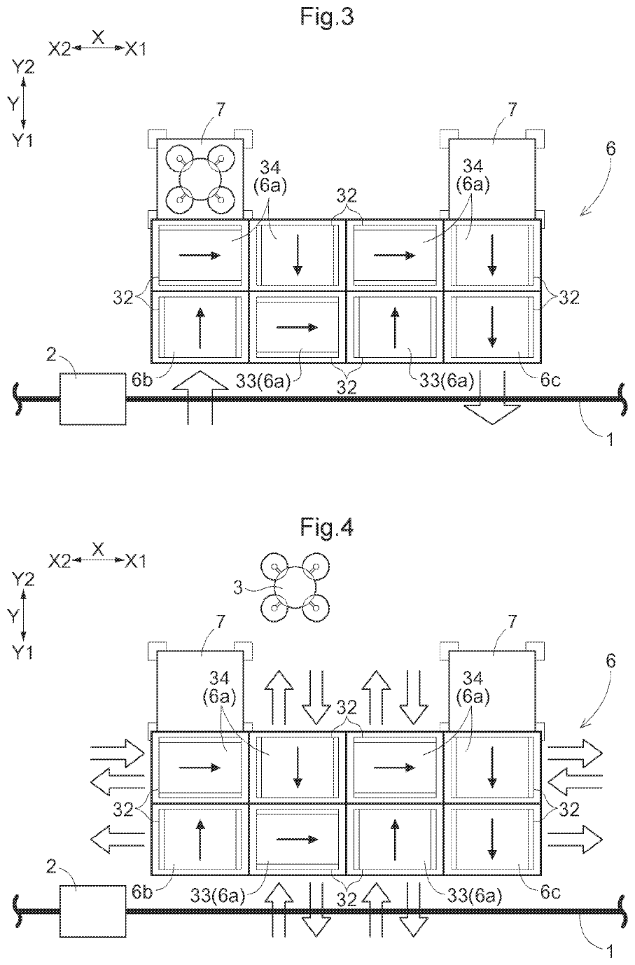

An article transport facility according to the present embodiment will be described below with reference to the drawings. A route extending direction X, a route width direction Y, and an up-down direction Z, which are three directions orthogonal to each other, are shown in the figures (see FIGS. 3 to 10). The route extending direction X is the direction along a travel route 1 (in FIG. 3 for example, the direction along straight portions of the travel route 1), a first side X1 is one side in the route extending direction X, and a second side X2 is the opposite side in the route extending direction X. The route width direction Y is the direction orthogonal to the route extending direction X (here, the horizontal direction orthogonal to the route extending direction X) in a vertical view along the up-down direction Z, a first side Y1 is one side in the route width direction Y, and a second side Y2 is the opposite side in the route width direction Y. A lower side Z1 and an upper side Z2 related to the up-down direction Z are also shown.

The article transport facility includes transport vehicles 2 that travel along a predetermined travel route 1 and transport articles 12, unmanned aerial vehicles 3 that fly along desired routes and transport articles 12, transfer sections 5 at which articles 12 are transferred to and from the transport vehicles 2 and the unmanned aerial vehicles 3, and storage units 6 that are arranged along the travel route 1 and store articles 12. The transport vehicles 2 transport the articles 12 from later-described carry-out sections 6c to the transfer sections 5.

In the illustrated example, the article transport facility includes a plurality of unmanned aerial vehicles 3, a plurality of transfer sections 5, and a plurality of storage units 6. The number of transport vehicles 2, the number of unmanned aerial vehicles 3, the number of processing devices 4, the number of transfer sections 5, and the number of storage units 6 in the article transport facility can be set as appropriate.

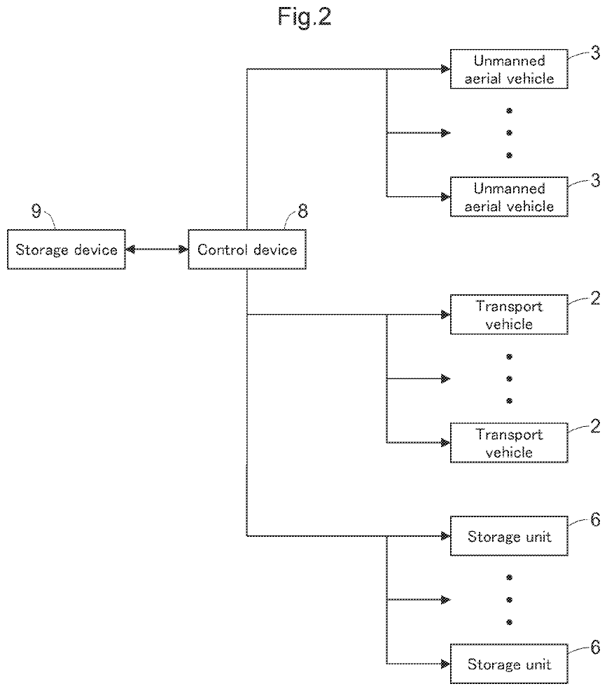

As shown in FIG. 2, the article transport facility further includes a control device 8, and also includes an information storage device 9 for storing information handled by the article transport facility. The control device 8 controls the unmanned aerial vehicles 3, the transport vehicles 2, and the storage units 6.

Processing Device

The processing devices 4 are semiconductor processing devices for performing various types of processing such as exposure processing and etching processing. In this case, in the article transport facility, the articles 12 that are transported are containers that contain a wafer for use as a semiconductor substrate, a reticle used for exposure processing of the wafer in the semiconductor substrate manufacturing process, and the like. For example, a reticle is transported in a dedicated container called a reticle pod. Also, a wafer is transported in a dedicated container called a FOUP (Front Opening Unified Pod). The processing devices 4 are each provided with a transfer section 5, and the articles 12 to be transported are carried in to and carried out from the processing devices 4 via the transfer sections 5. Alternatively, a target object (e.g., a wafer or a reticle) may be taken out of an article 12 on a transfer section 5 and carried in to the corresponding processing device 4, and a target object may be carried out from a processing device 4 and stored in an article 12 placed on the corresponding transfer section 5. The operations of the transport vehicles 2 when the transport vehicles 2 transfer articles 12 to and from the transfer sections 5 are similar to later-described operations of the transport vehicles 2 when the transport vehicles 2 transfer articles 12 to and from the storage units 6.

Transport Vehicle

The transport vehicles 2 can each transport an article 12 between a storage unit 6 and a transfer section 5. One or more transport vehicles 2 can be provided in the article transport facility, and the number of vehicles can be changed as appropriate. The transport vehicles 2 described in the present embodiment are so-called overhead transport vehicles that travel along the travel route 1 realized by rails installed on the ceiling of the space, for example.

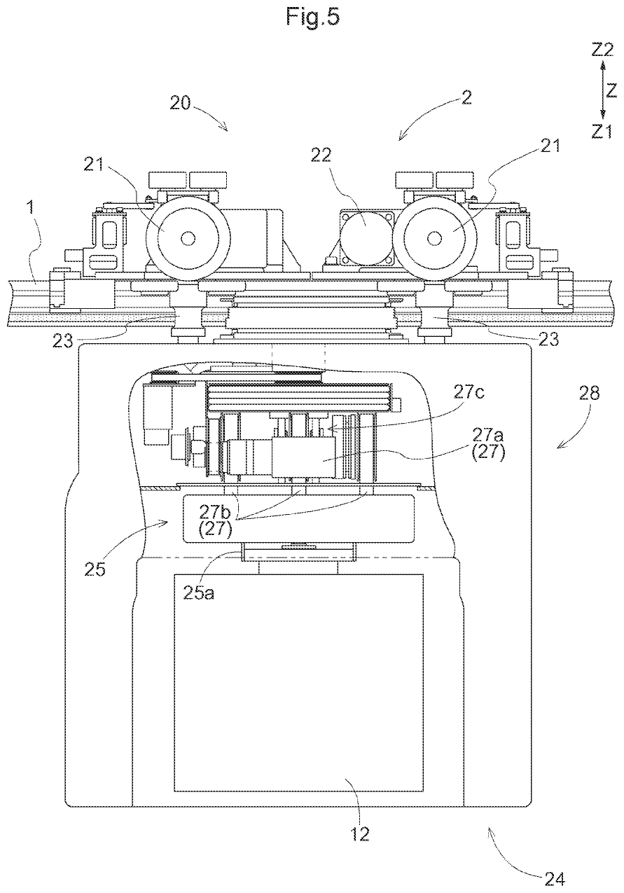

As shown in FIG. 5, each of the transport vehicles 2 includes a traveling section 20, a vehicle body section 24, and coupling sections 23 that couple the traveling section 20 and the vehicle body section 24 to each other. The traveling section 20 is arranged on the upper side Z2 of the travel route 1. The vehicle body section 24 is coupled to the traveling section 20 by the coupling sections 23, and is arranged on the lower side Z1 of the travel route 1. The transport vehicle 2 also includes a cover section 28 that covers the article 12 being transported by the transport vehicle 2.

The traveling section 20 has a plurality of traveling wheels 21 that roll on the travel route 1. At least one of the traveling wheels 21 is driven by a traveling motor 22 to roll on the travel route 1.

The vehicle body section 24 of the transport vehicle 2 includes the holding section 25 that holds an article 12 in a suspended orientation, and an elevating device 27 that raises and lowers the holding section 25, and the elevating device 27 lowers the holding section 25 from the upper side Z2 toward the carry-in section 6b and the carry-out section 6c and transfers an article 12 to or from the carry-in section 6b and the carry-out section 6c.

The holding section 25 is configured to hold the article 12 by gripping grip sections of the article 12. The holding section 25 has a pair of gripping claws 25a (only one of which is shown in FIG. 5) for gripping the grip sections of the article 12. By being driven by a gripping motor (not shown), the pair of gripping claws 25a can be changed between a gripping orientation of having been moved toward each other to grip the article 12, and a release orientation of having been moved away from each other to release the article 12.

The elevating device 27 raises and lowers the holding section 25 and the article 12 held thereby. In the present embodiment, the elevating device 27 includes elevating belts 27b coupled to the holding section 25, an elevating drum 27c around which the elevating belts 27b are wound, and an elevating motor 27a that drives the elevating drum 27c to rotate. When the elevating drum 27c is driven to rotate by the elevating motor 27a, the elevating belts 27b are wound in or wound out, that is to say, the holding section 25 is raised or lowered.

In the present embodiment, the storage unit 6 is not arranged on the lower side Z1 relative to the transport vehicle 2, but as will be described later, the carry-in section 6b and the carry-out section 6c, which are portions of the storage unit 6, protrude and retract along the route width direction Y (i.e., the carry-in section 6b and the carry-out section 6c move on the lower side Z1 relative to the transport vehicle 2) so that an article 12 can be carried in to the carry-in section 6b and carried out from the carry-out section 6c by the transport vehicle 2. Here “on the lower side Z1 relative to the transport vehicle 2” means a location that is on the lower side Z1 relative to the transport vehicle 2 while also overlapping the transport vehicle 2 in a vertical view.

Storage Device

The storage unit 6 includes the carry-in section 6b to which the transport vehicle 2 carries in an article 12, the carry-out section 6c from which the transport vehicle 2 carries out an article 12, at least one storage location 6a at which an article 12 is stored, and at least one transport device 32 that transports an article 12 to the carry-out section 6c via the storage location 6a.

FIG. 3 is a diagram in which white arrows show positions where the transport vehicle 2 can access the storage unit 6. The transport vehicle 2 is permitted access to carry in an article 12 to the carry-in section 6b of the storage unit 6, and is permitted to access to carry out an article 12 from the carry-out section 6c of the storage unit 6.

FIG. 4 is a diagram in which white arrows show positions where the unmanned aerial vehicle 3 can access the storage unit 6. The unmanned aerial vehicle 3 can access all of the storage locations 6a, the carry-in section 6b, and the carry-out section 6c. For example, the unmanned aerial vehicle 3 is permitted access for the carry-in of articles 12 and the carry-out of articles 12 at all of the storage locations 6a. Note that the unmanned aerial vehicle 3 is permitted access for the carry-out of articles 12 at the carry-in section 6b and the carry-out section 6c, but is not permitted access for the carry-in of articles 12 at the carry-in section 6b and the carry-out section 6c.

As a result, in the example shown in FIG. 4, the unmanned aerial vehicle 3 can transport an article 12 from all of the storage locations 6a to the transfer section 5 (carry-out), and transport an article 12 from the transfer section 5 to all of the storage locations 6a (carry-in). Also, the unmanned aerial vehicle 3 can transport an article 12 from the carry-in section 6b or the carry-out section 6c to the transfer section 5 (carry-out).

In the present embodiment, the storage unit 6 has three or more storage locations 6a. In the storage unit 6, the carry-in section 6b, the carry-out section 6c, and a specified storage location 33, which is at least one of the storage locations 6a, are arranged in a row along the travel route 1, and moreover, non-specified storage locations 34, which are the remaining storage locations 6a, are arranged parallel with the row including the carry-in section 6b, the carry-out section 6c, and the specified storage location 33. Also, the storage unit 6 has a plurality of storage levels 31 arranged next to each other in the up-down direction Z, each including a first row that extends in the route extending direction X and is made up of the carry-in section 6b, the carry-out section 6c, and the specified storage location 33, and further including a second row that extends in the route extending direction X, is made up of a plurality of the non-specified storage locations 34, and is arranged next to the first row in the route width direction Y. The transport devices 32 are provided in each of the storage levels 31.

In the illustrated example, the storage unit 6 has six storage locations 6a. The carry-in section 6b, the carry-out section 6c, and two specified storage locations 33 (two storage locations 6a) are aligned in a row along the travel route 1 on the first side Y1 in the width direction, and the remaining four non-specified storage locations 34 (four storage locations 6a) are aligned in a row along the travel route 1 on the second side Y2 in the width direction. Also, the storage unit 6 has two storage levels 31, one of the two storage levels 31 being a first storage level 31a and the other one being a second storage level 31b. The first storage level 31a provided on the upper side Z2 and the second storage level 31b provided on the lower side Z1 are arranged next to each other in the up-down direction Z.

A first carry-in section 61b is the carry-in section 6b of the first storage level 31a, a first carry-out section 61c is the carry-out section 6c of the first storage level 31a, a second carry-in section 62b is the carry-in section 6b of the second storage level 31b, and a second carry-out section 62c is the carry-out section 6c of the second storage level 31b. The first carry-in section 61b is overlapped with either the second carry-in section 62b or the second carry-out section 62c in a vertical view, and the first carry-out section 61c is overlapped with the other section out of the second carry-in section 62b and the second carry-out section 62c in a vertical view. Also, the first carry-in section 61b, the first carry-out section 61c, the second carry-in section 62b, and the second carry-out section 62c are configured to protrude and retract in the horizontal direction independently of each other with use of an electric motor or the like. Also, the direction of protrusion and retraction of the first carry-in section 61b, the first carry-out section 61c, the second carry-in section 62b, and the second carry-out section 62c is not limited to the horizontal direction, and such sections may be configured to protrude and retract in a direction upward or downward relative to the horizontal direction, for example, with use of an electric motor, its own weight, or the like.

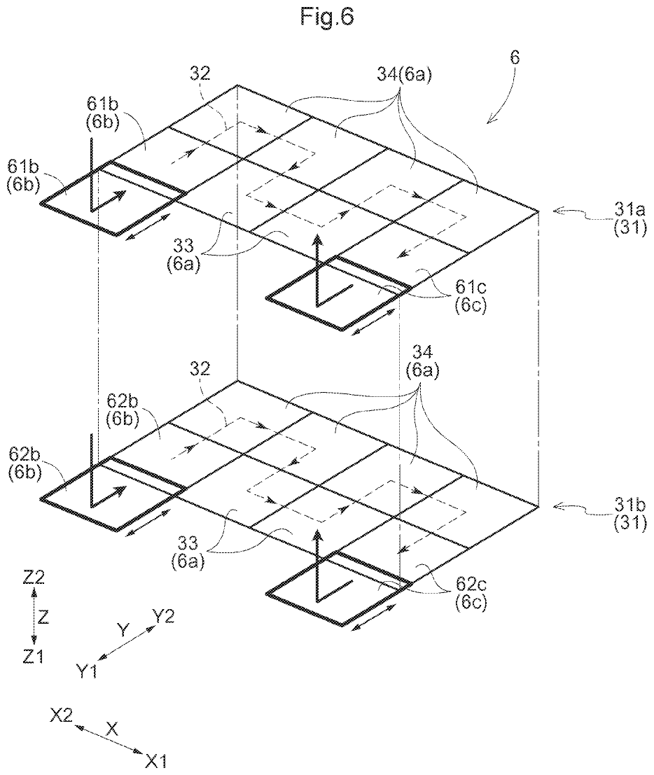

In the storage unit 6 shown in FIG. 6, the first carry-in section 61b and the second carry-in section 62b overlap each other in a vertical view, and the first carry-out section 61c and the second carry-out section 62c overlap each other in a vertical view. Note that the storage unit 6 may have a configuration in which the first carry-in section 61b and the second carry-out section 62c overlap each other in a vertical view, and the first carry-out section 61c and the second carry-in section 62b overlap each other in a vertical view.

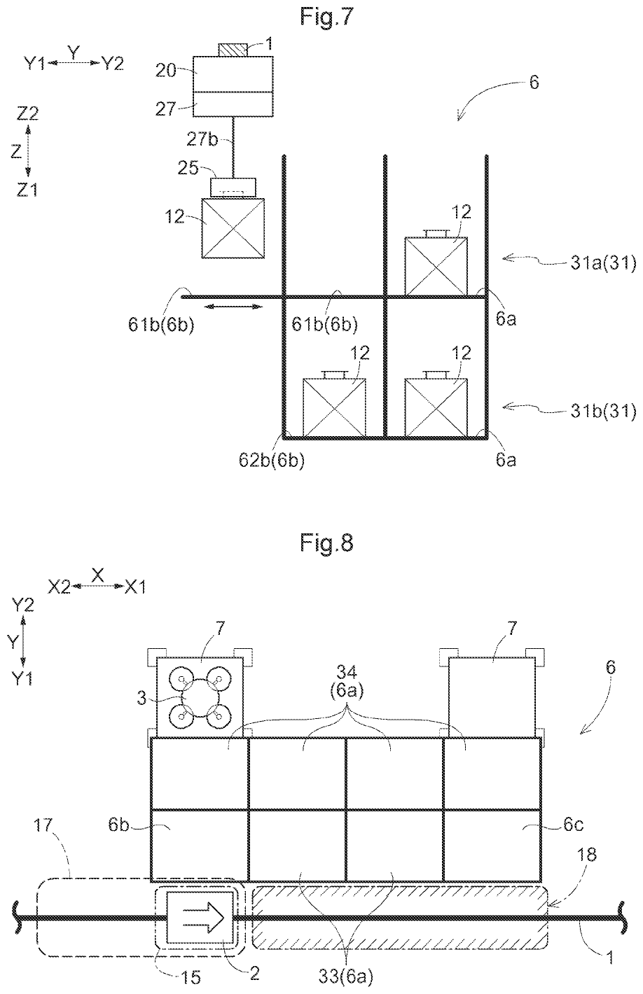

As shown in FIGS. 6 and 7, the carry-in section 6b can protrude and retract along the route width direction Y. When an article 12 transported by the transport vehicle 2 is to be carried in to the carry-in section 6b, the carry-in section 6b not having an article 12 placed thereon protrudes toward the first side Y1 in the width direction. The transport vehicle 2 transfers the article 12 to the protruding carry-in section 6b, and then the carry-in section 6b retracts toward the second side Y2 in the width direction, and thus the article 12 is stored in the storage unit 6.

The carry-out section 6c can also protrude and retract along the route width direction Y. When an article 12 is to be carried out from the carry-out section 6c by the transport vehicle 2, the carry-out section 6c having the article 12 placed thereon protrudes toward the first side Y1 in the width direction. The transport vehicle 2 receives the article 12 from the protruding carry-out section 6c. After that, the carry-out section 6c that transferred the article 12 to the transport vehicle 2 then retracts toward the second side Y2 in the width direction.

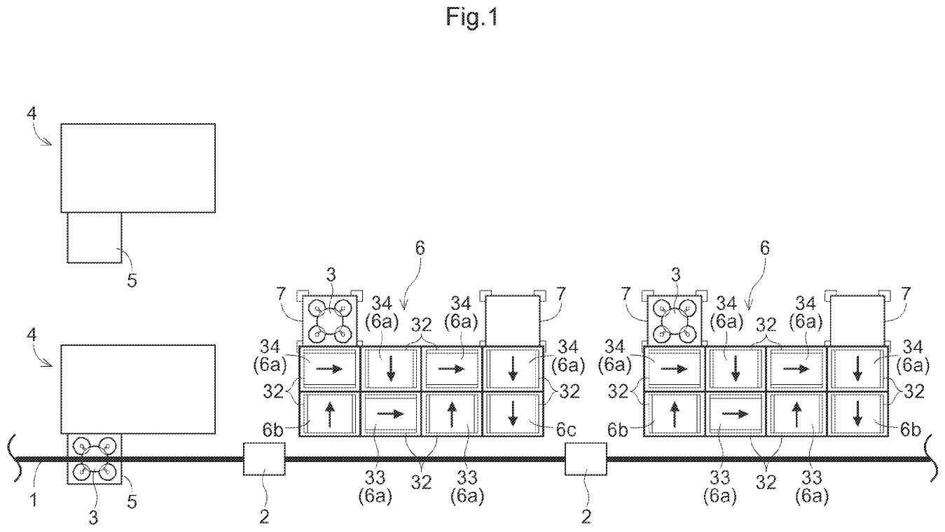

As shown in FIGS. 1, 3, 4, and 6, the storage unit 6 is provided with the transport devices 32 that transport articles 12 from the carry-in sections 6b to the carry-out sections 6c via the storage locations 6a. The transport devices 32 are conveyors, and the storage locations 6a are provided on the transport routes of the conveyors. For example, the transport devices 32 can be implemented using various types of conveyors, such as roller conveyors, belt conveyors, or chain conveyors.

In the drawings, the directions in which the articles 12 can be transported by the transport devices 32 are indicated by arrows. In each storage level, when an article 12 is carried in to the carry-in section 6b by the transport vehicle 2, the article 12 is transported across a plurality of storage locations 6a in the directions indicated by the arrows in the figure, and ultimately reaches the carry-out section 6c. In other words, in the illustrated example, an article 12 carried in to the carry-in section 6b passes through all of the storage locations 6a before reaching the carry-out section 6c. Alternatively, in the case where an article 12 is carried out to one of the storage locations 6a by the unmanned aerial vehicle 3 as well, the article 12 is transported across the storage locations 6a in the directions indicated by the arrows in the figure, and ultimately reaches the carry-out section 6c. Given that an article 12 is thus also stored while being transported by the transport devices 32, it can also be said that a transport device 32 includes a storage location 6a, or that a portion of the transport route of the transport devices 32 functions as a storage location 6a.

The storage unit 6 has a waiting site 7 where an unmanned aerial vehicle 3 can take off and land, and where an unmanned aerial vehicle 3 can wait. The waiting site 7 is a dedicated location for the landing of an unmanned aerial vehicle 3, and no articles 12 are stored at the waiting site 7. The waiting site 7 may be provided with power supply equipment for supplying power to the battery of the landed unmanned aerial vehicle 3, for example. In this case, while the unmanned aerial vehicle 3 has landed at the waiting site 7, the battery of the unmanned aerial vehicle 3 can be charged.

Given that both the transport vehicle 2 and the unmanned aerial vehicle 3 operate near the carry-in section 6b and the carry-out section 6c, a collision between the transport vehicle 2 and the unmanned aerial vehicle 3 can possibly occur near the carry-in section 6b and the carry-out section 6c. In the present embodiment, letting a transport vehicle stop location 15 along the travel route 1 be a location at which the transport vehicle 2 stops in order to carry in an article 12 to the carry-in section 6b or carry out an article 12 from the carry-out section 6c, in order to prevent a collision such as that described above, as shown in FIG. 8, in the case where the transport vehicle 2 is in a specified range 17 that includes the transport vehicle stop location 15, the control device 8 prohibits arrival of the unmanned aerial vehicle 3 at the carry-in section 6b and the carry-out section 6c, and also prohibits entry of the unmanned aerial vehicle 3 into a given range (i.e., a range 18 shown in FIG. 8) that extends forward in the travel direction of the transport vehicle 2 (i.e., extends toward the first side X1 in the extending direction) from the transport vehicle stop location 15. Note that FIG. 8 shows a situation in which the transport vehicle 2 carries in an article 12 to the carry-in section 6b, and therefore, the transport vehicle stop location 15 shown in FIG. 8 is the location at which the transport vehicle 2 stops in order to carry in the article 12 to the carry-in section 6b.

### 2. Other Embodiments

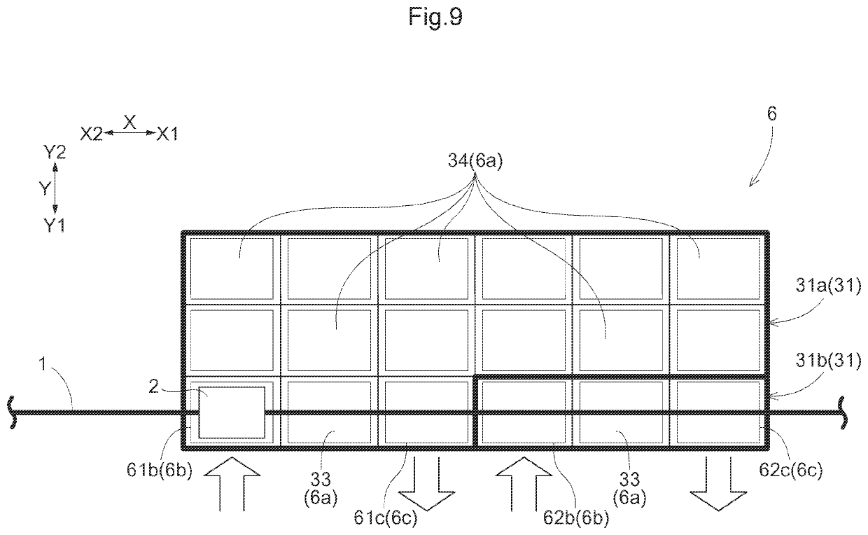

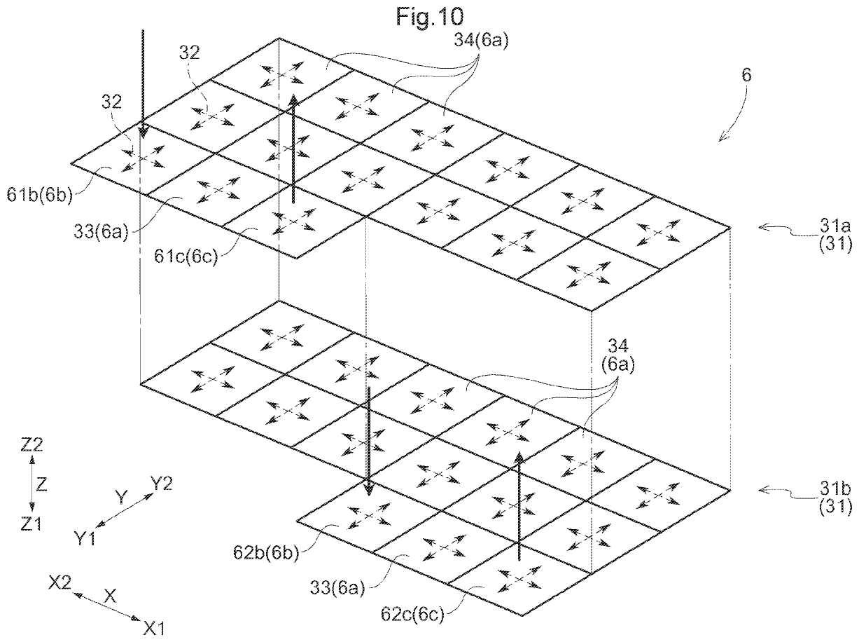

Next, other embodiments of the article transport facility will be described.
(1) Although the transport vehicle 2 is an overhead transport vehicle in the above embodiment, the transport vehicle 2 is not limited to this. For example, the transport vehicle 2 may be another moving body such as an AGV (Automated Guided Vehicle) or an STV (Sorting Transfer Vehicle).
(2) Although the processing device 4 is a semiconductor processing device in the above embodiment, the processing device 4 is not limited to this. For example, the processing device 4 may be a sorting device that sorts the articles 12. In this case, the articles 12 are containers containing a plurality of products, for example. Alternatively, the processing device 4 may be a manufacturing device or the like that manufactures products. In this case, the articles 12 are the products manufactured by the manufacturing device.
(3) In the above embodiment, the arrangement of the carry-in section 6b, the carry-out section 6c, and the storage locations 6a in the storage levels 31 can be changed as appropriate. The storage unit 6 shown in FIGS. 9 and 10 has the first storage level 31a and the second storage level 31b that are arranged next to each other in the up-down direction Z. However, the first storage level 31a and the second storage level 31b have different shapes from each other. Specifically, the first carry-in section 61b of the first storage level 31a and the second carry-in section 62b of the second storage level 31b do not overlap each other when viewed in the up-down direction Z. Also, the first carry-out section 61c of the first storage level 31a and the second carry-out section 62c of the second storage level 31b do not overlap each other when viewed in the up-down direction Z.

Furthermore, the first carry-in section 61b and the first carry-out section 61c of the first storage level 31a are not provided with a protrude/retract mechanism, and the second carry-in section 62b and the second carry-out section 62c of the second storage level 31b are not provided with a protrude/retract mechanism. It should be noted that since the first carry-in section 61b of the first storage level 31a and the second carry-in section 62b of the second storage level 31b do not overlap each other in a vertical view, and since the first carry-out section 61c of the first storage level 31a and the second carry-out section 62c of the second storage level 31b do not overlap each other in a vertical view, as shown in FIG. 9, the region above the first carry-in section 61b and the first carry-out section 61c of the first storage level 31a and the region above the second carry-out section 62c and the second carry-in section 62b of the second storage level 31b are open and accessible by the transport vehicle 2.

In other words, in a case of carrying in an article 12 to the carry-in section 6b of the first storage level 31a, the transport vehicle 2 may stop above the carry-in section 6b of the first storage level 31a, lower the article 12 held by the holding section 25 to the carry-in section 6b, and transfer the article 12 to the carry-in section 6b. In a case of carrying out an article 12 from the carry-out section 6c of the first storage level 31a, the transport vehicle 2 may stop above the carry-out section 6c of the first storage level 31a, lower the holding section 25 to the carry-out section 6c, and receive the article 12 with the holding section 25.

In a case of carrying in an article 12 to the carry-in section 6b of the second storage level 31b, the transport vehicle 2 may stop above the carry-in section 6b of the second storage level 31b, lower the article 12 held by the holding section 25 to the carry-in section 6b, and transfer the article 12 to the carry-in section 6b. In a case of carrying out an article 12 from the carry-out section 6c of the second storage level 31b, the transport vehicle 2 may stop above the carry-out section 6c of the second storage level 31b, lower the holding section 25 to the carry-out section 6c, and receive the article 12 with the holding section 25.

Also, the transport devices 32 shown in FIGS. 9 and 10 can transport articles 12 along the route extending direction X and also transport articles 12 along the route width direction Y as indicated by dashed arrows (see FIG. 10). The use of such transport devices 32 makes it possible for articles 12 to be transported via a desired route to a desired position. For example, an article 12 carried in to the carry-in section 6b can be transported to the carry-out section 6c via one specified storage location 33 between the carry-in section 6b and the carry-out section 6c. In other words, in the configuration in the above-described embodiment, there is one transport route for the articles 12 in the storage unit 6, and for example, the article 12 that is carried in to the carry-in section 6b of the storage unit 6 the soonest is carried out from the carry-out section 6c the soonest (i.e., a first-in first-out configuration), but the storage unit 6 shown in FIGS. 9 and 10 is configured such that the articles 12 carried in to the carry-in section 6b can be carried out from the carry-out section 6c in any order.
(4) In the above embodiment, an example is described in which each of the storage levels 31 includes the transport devices 32, but the storage unit 6 may include a storage level 31 that is not provided with any transport devices 32. In the case where there is a storage level 31 not provided with the transport devices 32, the articles 12 may be transported in the storage unit 6 by the unmanned aerial vehicle 3.
(5) In the above-described embodiment, it is possible to appropriately set the locations in the storage unit 6 to which articles 12 are to be carried in by the transport vehicle 2 and the unmanned aerial vehicle 3, and appropriately set the locations in the storage unit 6 from which articles 12 are to be carried out by the transport vehicle 2 and the unmanned aerial vehicle 3.

The unmanned aerial vehicle 3 may be configured to transport (carry out) the articles 12 from at least either the carry-in section 6b or the carry-out section 6c to the transfer section 5. A configuration is possible in which the unmanned aerial vehicle 3 does not transport the articles 12 between the carry-out section 6c and the transfer section 5, or does not transport the articles 12 between the carry-in section 6b and the transfer section 5. The unmanned aerial vehicle 3 may be configured to carry out the articles 12 from the carry-in section 6b, the carry-out section 6c, and all of the storage location 6a, and to carry-in the articles 12 to at least one of the storage locations 6a.
(6) Although an example of the configuration of the storage location 6a in the storage unit 6 is described in the above embodiment, the configuration of the storage location 6a in the storage unit 6 can be changed as appropriate. For example, the storage unit 6 may be an automated warehouse having a stacker crane or the like, or a storage area set on the floor, for example. In the case where the storage unit 6 uses an automated warehouse having a stacker crane, the functions of the transport devices 32 may be realized using the functions of the stacker crane. In this case, an article 12 carried in to the carry-in section 6b may be directly transported to the carry-out section 6c using the stacker crane.
(7) In the above embodiment, the storage unit 6 may have a configuration in which the first row, which is made up of the carry-in section 6b, the carry-out section 6c, and the specified storage location 33, and the second row, which is made up of the non-specified storage locations 34, are arranged next to each other in the up-down direction Z. In this case, the transport of the articles 12 between the first row and the second row can be performed using the above-described stacker crane functioning as the transport devices 32, for example.

Also, the storage unit 6 may have a plurality of the second rows made up of the non-specified storage locations 34. In other words, the storage unit 6 may have a configuration including a first row and a plurality of second rows (i.e., a configuration including three or more rows). In this case, the rows may be arranged next to each other in the route width direction Y, or may be arranged next to each other in the up-down direction Z.

Furthermore, the storage unit 6 may have three or more storage levels 31.
(8) In the above embodiment, the waiting site 7 may be disposed at another location. For example, the waiting site 7 may be disposed adjacent to the transfer section 5, or may be disposed at a position away from the storage unit 6 and the transfer section 5.
(9) In the above embodiment, the unmanned aerial vehicle 3 may have a wired-connection configuration and have a feeder line, a signal line, or the like connected thereto. In this case, the waiting site 7 may be provided with a winding device or the like for the power supply line, the signal line, or the like.
(10) In the above embodiment, the direction in which the carry-in section 6b and the carry-out section 6c protrude and retract may be a direction other than the route width direction Y. For example, the carry-in section 6b and the carry-out section 6c may protrude and retract in the route extending direction X.

Also, the carry-in section 6b and the carry-out section 6c may protrude and retract in different directions from each other. For example, a configuration is possible in which the carry-in section 6b protrudes and retracts in the route width direction Y, and the carry-out section 6c protrudes and retracts in the route extending direction X.
(11) In the above embodiment, an example is described in which the control device 8 controls the operations of the transport vehicles 2, the unmanned aerial vehicles 3, and the storage units 6 as shown in FIG. 2, for example, but the configuration of the control device 8 can be changed as appropriate. For example, a configuration is also possible in which the control device 8 is provided as a device for integrally controlling a plurality of controllers provided in the article transport facility, such as a controller provided for controlling the operations of the transport vehicles 2, a controller provided for controlling the operations of the unmanned aerial vehicles 3, and a controller provided for controlling operations of the storage units 6. Alternatively, the functions of the control device 8 may be performed by an existing controller provided in the article transport facility, such as a controller provided to control the operations of the transport vehicles 2.

### 3. Overview of Embodiments

The following describes an overview of the article transport facility described above.

An article transport facility according to an aspect includes: a transport vehicle configured to travel along a predetermined travel route and transport an article; an unmanned aerial vehicle configured to fly along a route and transport the article; a transfer section at which the article is transferrable to and from the transport vehicle and the unmanned aerial vehicle; and a storage unit arranged at a location along the travel route and configured to store the article, wherein the storage unit includes: a carry-in section to which the transport vehicle carries in the article; a carry-out section from which the transport vehicle carries out the article; at least one storage location at which the article is storable; and a transport device configured to transport the article from the carry-in section to the carry-out section via the at least one storage location, the transport vehicle transports the article from the carry-out section to the transfer section, and the unmanned aerial vehicle transports the article from the at least one storage location to the transfer section.

According to this configuration, an article stored at a storage location between the carry-in section and the carry-out section of the storage unit can be transported by the unmanned aerial vehicle. Therefore, even if an article stored in the storage unit cannot be immediately transported to the transfer section of the processing device by the transport vehicle, the article can be quickly transported from the storage unit to the transfer section of the processing device by the unmanned aerial vehicle. Also, in the case where an article becomes needed in the processing device or processing of an article in the processing device is complete, the article can be quickly transported by the unmanned aerial vehicle, without waiting for the arrival of the transport vehicle. Therefore, it is easy to improve the efficiency of article transport between the storage unit and the transfer section, thus making it is easy to improve the efficiency of article processing performed by the processing device. It is thus possible to realize an article transport facility that can efficiently transport articles.

Here, it is preferable that the unmanned aerial vehicle furthermore transports the article from at least one of the carry-in section and the carry-out section to the transfer section.

According to this configuration, an article stored in at least either the carry-in section or the carry-out section of the storage unit can be transported not only by the transport vehicle but also by the unmanned aerial vehicle. Therefore, articles stored at such locations can be quickly transported to the transfer section using the unmanned aerial vehicle, without waiting for the arrival of the transport vehicle.

Here, it is preferable that the storage unit has a waiting site at which the unmanned aerial vehicle is capable of taking off and landing, and at which the unmanned aerial vehicle that landed is capable of waiting.

According to this configuration, the unmanned aerial vehicle can be caused to wait at a position near articles stored in the storage unit. For this reason, when it becomes possible to carry in an article to the transfer section, the article can be quickly transported from the storage unit to the transfer section by the unmanned aerial vehicle. Therefore, it is easy to improve the efficiency of article transport between the storage unit and the transfer section, thus making it is easy to improve the overall article transport efficiency of the article transport facility.

Here, it is preferable that the unmanned aerial vehicle carries out the article from the carry-in section, the carry-out section, and all of the at least one storage location, and carries in the article to the at least one storage location.

According to this configuration, an article can be carried in to the storage unit not only by the transport vehicle but also by the unmanned aerial vehicle. Therefore, articles can be efficiently transported throughout the entirety of the article transport facility. Also, the transport vehicle carries in articles to the carry-in section of the storage unit, and the unmanned aerial vehicle carries in articles to the storage locations of the storage unit. In other words, in the storage unit, the position where the transport vehicle carries in articles is provided separately from the positions where the unmanned aerial vehicle carries in articles. As a result, it is possible to avoid interference between the carry-in of articles to the storage unit by the transport vehicle and the carry-in of articles to the storage unit by the unmanned aerial vehicle. For example, it is possible to avoid a situation in which either the transport vehicle or the unmanned aerial vehicle needs to wait to carry in an article while the other one is carrying in an article to the storage unit. Therefore, in this respect as well, articles can be efficiently transported throughout the entirety of the article transport facility.

Here, it is preferable that the transport device is a conveyor, and the at least one storage location is provided on a transport route of the conveyor.

According to this configuration, it is possible to realize a transport device in which an article can be transported from the carry-in section to the carry-out section via the storage locations with a simple configuration.

Here, it is preferable that the storage unit includes three or more storage locations corresponding to the at least one storage location, the carry-in section, the carry-out section, and at least one specified storage location that is at least one of the three or more storage locations are aligned in a row along the travel route, and at least one non-specified storage location that is at least one of the three or more storage locations other than the at least one specified storage location is arranged parallel with the row including the carry-in section, the carry-out section, and the at least one specified storage location.

According to this configuration, the number of storage locations increases, and thus a larger number of articles can be stored in the storage unit. Also, instead of the carry-in section, the carry-out section, and all of the storage locations being aligned in one row, the row that includes the specified storage location is arranged parallel with the row that includes the non-specified storage locations, thus making the storage unit compact. Therefore, a relatively large number of articles can be stored in the storage unit while suppressing an increase in the size of the storage unit.

Here, it is preferable that a direction along the travel route is a route extending direction, and a direction orthogonal to the route extending direction in a vertical view along an up-down direction is a route width direction, the storage unit has a plurality of storage levels each including (i) a first row including the carry-in section, the carry-out section, and the at least one specified storage location, and (ii) a second row including the at least one non-specified storage location, the first row and the second row being arranged next to each other in the route width direction, the plurality of storage levels are arranged next to each other in the up-down direction, and the transport device is provided in each of the plurality of storage levels.

According to this configuration, space in the up-down direction is utilized, thus making it possible to store a relatively large number of articles in the storage unit while suppressing an increase in the size of the storage unit.

Here, it is preferable that the transport vehicle includes: a holding section configured to hold the article in a suspended orientation; and an elevating device configured to raise and lower the holding section, the elevating device lowers the holding section from above toward the carry-in section and the carry-out section to transfer the article to and from the carry-in section and the carry-out section, one of the plurality of storage levels is a first storage level, another of the plurality of storage levels is a second storage level, the carry-in section in the first storage level is a first carry-in section, the carry-out section in the first storage level is a first carry-out section, the carry-in section in the second storage level is a second carry-in section, and the carry-out section in the second storage level is a second carry-out section, the first carry-in section overlaps one of the second carry-in section and the second carry-out section in the vertical view, and the first carry-out section overlaps the other of the second carry-in section and the second carry-out section in the vertical view, and the first carry-in section, the first carry-out section, the second carry-in section, and the second carry-out section protrude and retract in a horizontal direction independently of each other.

According to this configuration, the first carry-in section and the first carry-out section on the first storage level and the second carry-in section and the second carry-out section on the second storage level of the storage unit can protrude and retract in the horizontal direction independently of each other. In other words, among the first carry-in section, the first carry-out section, the second carry-in section, and the second carry-out section to and from which articles are transferred by the transport vehicle, if only one of them protrudes in the horizontal direction, an article can be transferred to or from that section while avoiding interference with another carry-in section or carry-out section. Therefore, articles can be appropriately transferred between the storage unit and the transport vehicle even if the storage unit has a plurality of storage levels in the up-down direction.

Here, it is preferable that the article transport facility further includes: a control device configured to control a plurality of unmanned aerial vehicles each corresponding to the unmanned aerial vehicle, wherein in response to the transport vehicle being in a specified range including a transport vehicle stop location, which is a location along the travel route at which the transport vehicle stops in order to carry in the article to the carry-in section or carry out the article from the carry-out section, the control device prohibits (i) arrival of the plurality of unmanned aerial vehicles at the carry-in section and the carry-out section, and (ii) entry of the plurality of unmanned aerial vehicles into a given range extending forward in a travel direction of the transport vehicle from the transport vehicle stop location.

According to this configuration, it is possible to avoid interference between the transport vehicle and the unmanned aerial vehicle while controlling the flight of the unmanned aerial vehicle.

### INDUSTRIAL APPLICABILITY

The present invention is applicable to an article transport facility that can efficiently transport articles.

1. An article transport facility comprising:
a transport vehicle configured to travel along a predetermined travel route and transport an article;
an unmanned aerial vehicle configured to fly along a route and transport the article;
a transfer section at which the article is transferrable to and from the transport vehicle and the unmanned aerial vehicle; and
a storage unit arranged at a location along the travel route and configured to store the article,
wherein;
the storage unit comprises:
a carry-in section to which the transport vehicle carries in the article;
a carry-out section from which the transport vehicle carries out the article;
at least one storage location at which the article is storable; and
a transport device configured to transport the article from the carry-in section to the carry-out section via the at least one storage location,
the transport vehicle transports the article from the carry-out section to the transfer section, and
the unmanned aerial vehicle transports the article from the at least one storage location to the transfer section.

2. The article transport facility according to claim 1,
wherein the unmanned aerial vehicle furthermore transports the article from at least one of the carry-in section and the carry-out section to the transfer section.

3. The article transport facility according to claim 2,
wherein the storage unit has a waiting site at which the unmanned aerial vehicle is capable of taking off and landing, and at which the unmanned aerial vehicle that landed is capable of waiting.

4. The article transport facility according to claim 2,
wherein the unmanned aerial vehicle carries out the article from the carry-in section, the carry-out section, and all of the at least one storage location, and carries in the article to the at least one storage location.

5. The article transport facility according to claim 1,
wherein the transport device is a conveyor, and
wherein the at least one storage location is provided on a transport route of the conveyor.

6. The article transport facility according to claim 1, wherein:
the storage unit comprises three or more storage locations corresponding to the at least one storage location,
the carry-in section, the carry-out section, and at least one specified storage location that is at least one of the three or more storage locations are aligned in a row along the travel route, and
at least one non-specified storage location that is at least one of the three or more storage locations other than the at least one specified storage location is arranged parallel with the row including the carry-in section, the carry-out section, and the at least one specified storage location.

7. The article transport facility according to claim 6, wherein:
a direction along the travel route is a route extending direction, and a direction orthogonal to the route extending direction in a vertical view along an up-down direction is a route width direction,
the storage unit has a plurality of storage levels each comprising (i) a first row including the carry-in section, the carry-out section, and the at least one specified storage location, and (ii) a second row including the at least one non-specified storage location, the first row and the second row arranged next to each other in the route width direction,
the plurality of storage levels are arranged next to each other in the up-down direction, and
the transport device is provided in each of the plurality of storage levels.

8. The article transport facility according to claim 7, wherein:
the transport vehicle comprises:
a holding section configured to hold the article in a suspended orientation; and
an elevating device configured to raise and lower the holding section,
the elevating device lowers the holding section from above toward the carry-in section and the carry-out section to transfer the article to and from the carry-in section and the carry-out section,
one of the plurality of storage levels is a first storage level, another of the plurality of storage levels is a second storage level, the carry-in section in the first storage level is a first carry-in section, the carry-out section in the first storage level is a first carry-out section, the carry-in section in the second storage level is a second carry-in section, and the carry-out section in the second storage level is a second carry-out section,
the first carry-in section overlaps one of the second carry-in section and the second carry-out section in the vertical view, and the first carry-out section overlaps the other of the second carry-in section and the second carry-out section in the vertical view, and
the first carry-in section, the first carry-out section, the second carry-in section, and the second carry-out section protrude and retract in a horizontal direction independently of each other.

9. The article transport facility according to claim 1, further comprises:
a control device configured to control a plurality of unmanned aerial vehicles each corresponding to the unmanned aerial vehicle, and
wherein in response to the transport vehicle being in a specified range including a transport vehicle stop location, which is a location along the travel route at which the transport vehicle stops in order to carry in the article to the carry-in section or carry out the article from the carry-out section, the control device prohibits (i) arrival of the plurality of unmanned aerial vehicles at the carry-in section and the carry-out section, and (ii) entry of the plurality of unmanned aerial vehicles into a given range extending forward in a travel direction of the transport vehicle from the transport vehicle stop location.
